(19) United States
(12) Patent Application Publication
(10) Pub. No.: US 2015/0044614 A1
(43) Pub. Date: Feb. 12, 2015

(54) DRAWING APPARATUS, AND METHOD OF MANUFACTURING ARTICLE

(71) Applicant: CANON KABUSHIKI KAISHA, Tokyo (JP)

(72) Inventors: Koichi SENTOKU, Kawachi-gun (JP); Masato MURAKI, Inagi-shi (JP)

(21) Appl. No.: 14/444,254

(22) Filed: Jul. 28, 2014

(30) Foreign Application Priority Data
Aug. 12, 2013 (JP) 2013-167842

(51) Int. Cl. H01J 37/304; G03F 7/20

(52) U.S. Cl. CPC H01J 37/3045; G03F 7/2037
USPC 430/296; 250/396 R

(57) ABSTRACT

The present invention provides a drawing apparatus which performs drawing on a substrate with a plurality of charged particle beams, the apparatus comprising a blanker array including a plurality of blankers and configured to individually blank the plurality of charged particle beams, a plurality of deflectors configured to individually deflect a plurality of charged particle beam groups constituting the plurality of charged particle beams, and a controller configured to individually control positions of the plurality of charged particle beam groups by the plurality of deflectors, and individually control blanking of the plurality of charged particle beams by the blanker array, based on information of a region on the substrate where a shot region exists.

### BACKGROUND OF THE INVENTION

1. Field of the Invention

The present invention relates to a drawing apparatus, and a method of manufacturing an article.

2. Description of the Related Art

Along with micropatterning and high integration of circuit patterns in semiconductor devices, attention is paid to a drawing apparatus which draws a pattern on a substrate with a plurality of charged particle beams (electron beams). A semiconductor device is manufactured by overlaying a plurality of patterns on one substrate. It is therefore important for the drawing apparatus to draw a pattern at high precision in a shot region formed on a substrate.

However, a shot region formed on a substrate is sometimes formed in a shape different from a shape to be originally formed, that is, is deformed and formed. If a shot region is deformed and formed on a substrate, it may become difficult to draw a pattern in the shot region at high overlay precision. To solve this, Japanese Patent No. 3647128 has proposed a drawing apparatus in which, when the shape of a shot region formed on a substrate contains a magnification component, the interval between a plurality of charged particle beams irradiating the substrate is changed to correct the magnification component.

It is rare that the deformation component of a shot region formed on a substrate contains only a magnification component. In general, the deformation component may contain a component such as a rotation component. In this case, it is difficult to correct the rotation component in the shot region by only changing the interval between a plurality of charged particle beams irradiating a substrate, as in the drawing apparatus described in Japanese Patent No. 3647128.

### SUMMARY OF THE INVENTION

The present invention provides, for example, a drawing apparatus advantageous in terms of overlay precision.

According to one aspect of the present invention, there is provided a drawing apparatus which performs drawing on a substrate with a plurality of charged particle beams, the apparatus comprising: a blanker array including a plurality of blankers and configured to individually blank the plurality of charged particle beams; a plurality of deflectors configured to individually deflect a plurality of charged particle beam groups constituting the plurality of charged particle beams; and a controller configured to individually control positions of the plurality of charged particle beam groups by the plurality of deflectors, and individually control blanking of the plurality of charged particle beams by the blanker array, based on information of a region on the substrate where a shot region exists.

Further features of the present invention will become apparent from the following description of exemplary embodiments with reference to the attached drawings.

### BRIEF DESCRIPTION OF THE DRAWINGS

FIG. 1 is a schematic view showing a drawing apparatus according to the first embodiment;

FIG. 2 is a view showing the arrangement of a drawing unit according to the first embodiment;

FIG. 3 is a view showing the arrangement of shot regions and alignment marks formed on a substrate;

FIG. 4A is a view showing the arrangement of shot regions, and regions where drawing is performed with a charged particle beam group;

FIG. 4B is a view showing the arrangement of shot regions, and regions where drawing is performed with a charged particle beam group;

FIG. 4C is a view showing the arrangement of shot regions, and regions where drawing is performed with a charged particle beam group;

FIG. 5A is a view showing the arrangement of shot regions, and regions where drawing is performed with a charged particle beam group;

FIG. 5B is a view showing the arrangement of shot regions, and regions where drawing is performed with a charged particle beam group;

FIG. 6 is a view showing the arrangement of shot regions, and regions where drawing is performed with a charged particle beam group;

FIG. 7 is a view showing a step of performing drawing with a subject (or intended) charged particle beam array;

FIG. 8 is a view showing a step of performing drawing with a subject charged particle beam array;

FIG. 9 is a view showing the arrangement of shot regions, and regions where drawing is performed with a charged particle beam group;

FIG. 10 is a view showing a step of performing drawing with a subject charged particle beam array; and

FIG. 11 is a view showing the arrangement of shot regions, and regions where drawing is performed with a charged particle beam group.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given.

### First Embodiment

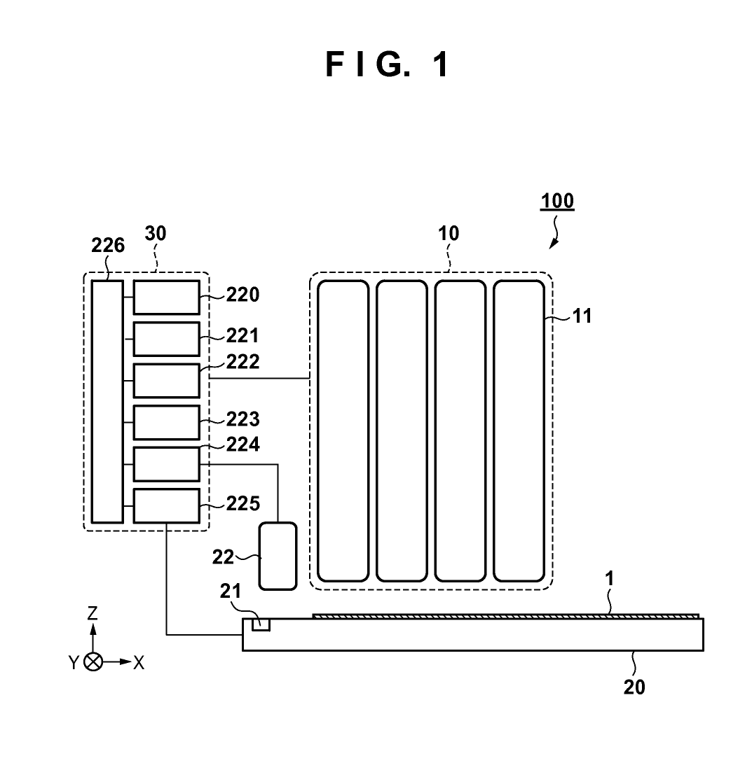

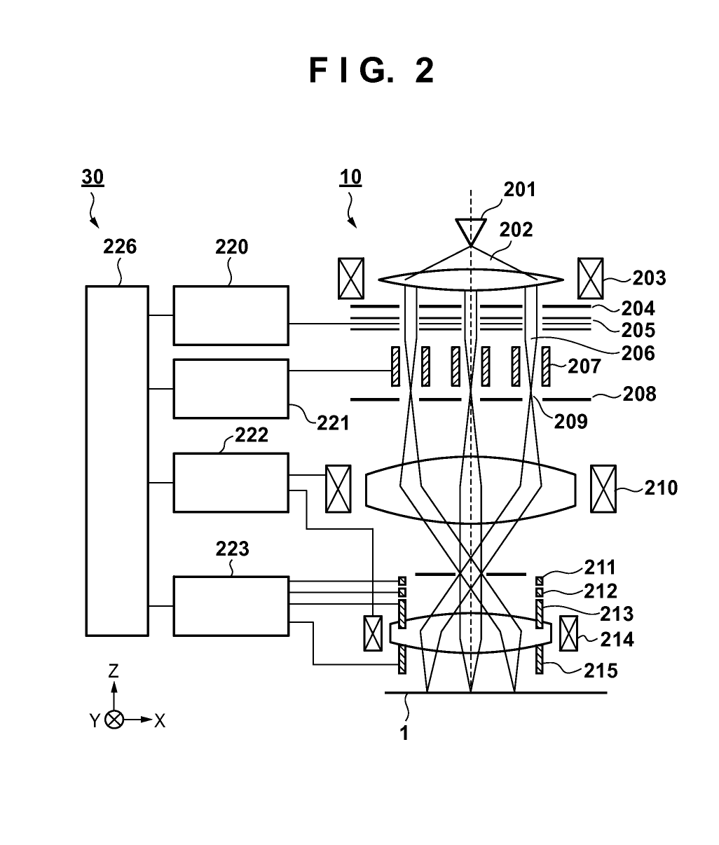

A drawing apparatus 100 according to the first embodiment of the present invention will be explained with reference to FIG. 1. The drawing apparatus 100 according to the first embodiment includes a drawing system 10 which performs drawing on a substrate with a plurality of charged particle beam groups each including a plurality of charged particle beams, a substrate stage 20 which is movable while holding a substrate, and a control system 30 which controls the drawing system 10 and substrate stage 20. The drawing system 10 according to the first embodiment includes, for example, a plurality of drawing units 11 in correspondence with the respective charged particle beam groups. Each drawing unit 11 irradiates a substrate 1 with a plurality of charged particle beams. That is, a plurality of charged particle beams emitted from one drawing unit 11 constitute one charged particle beam group. The arrangement of the drawing unit 11 will be explained with reference to FIG. 2.

A charged particle source 201 uses, for example, a thermoelectron emitting electron source containing an electron emitting material such as LaB₆. A condenser lens 203 changes a charged particle beam 202 emitted by the charged particle source 201 into a parallel beam, and the parallel beam enters an aperture array 204. The aperture array has a plurality of openings, and splits the charged particle beam 202 incident as the parallel beam into a plurality of charged particle beams. The charged particle beams split by the aperture array 204 enter a lens array 205. The lens array 205 is constituted by three electrode plates in which a plurality of openings are formed. By giving a potential difference between the central electrode plate, and the upper and lower electrode plates sandwiching it, the plurality of openings can function as lenses. Each charged particle beam having passed through the lens array 205 forms an intermediate image 209 of the crossover image of the charged particle source near a blanking aperture 208 by the action of the lens array 205. The position of the intermediate image 209 changes in the optical axis direction (Z direction) by changing a voltage applied to the lens array 205. A blanker array 207 having a plurality of blankers for individually blanking a plurality of split charged particle beams is interposed between the lens array 205 and the blanking aperture 208. Each blanker constituting the blanker array 207 is formed from, for example, two facing electrodes. The blanker generates an electric field by applying a voltage between the two electrodes, and can deflect a charged particle beam. The charged particle beam deflected by the blanker is blocked by the blanking aperture 208 and does not reach the substrate. To the contrary, a charged particle beam not deflected by the blanker passes through the opening formed in the blanking aperture 208, and reaches the substrate. That is, the blanker array 207 individually switches a charged particle beam between irradiation and no irradiation of the substrate 1.

A charged particle beam having passed through the blanking aperture 208 passes through a first projection lens 210 and second projection lens 214. Accordingly, the intermediate image 209 formed near the blanking aperture 208 is projected on the substrate. A lens control unit 222 (to be described later) controls the first projection lens 210 and second projection lens 214 so that a focus position at the rear stage of the first projection lens 210 and a focus position at the front stage of the second projection lens 214 coincide with each other. This arrangement of the first projection lens 210 and second projection lens 214 is called a symmetrical magnetic tablet lens configuration, and the intermediate image 209 can be projected on the substrate 1 with low aberration. A plurality of charged particle beams irradiating the substrate 1 are deflected at once by a main deflector 213 and sub-deflector 215 and can be scanned on the substrate. For example, an electromagnetic deflector is used as the main deflector 213, and an electrostatic deflector is used as the sub-deflector 215. The sub-deflector 215 is configured so that the amount by which a plurality of charged particle beams are deflected becomes smaller than that by the main deflector 213. The sub-deflector 215 can finely adjust deflection of a plurality of charged particle beams. A dynamic focus corrector 211 corrects a defocus caused by deflection aberration generated when the main deflector 213 and sub-deflector 215 deflect a plurality of charged particle beams. Similar to the dynamic focus corrector 211, a dynamic astigmatism corrector 212 corrects astigmatism generated by deflection of a plurality of charged particle beams. The dynamic focus corrector 211 and dynamic astigmatism corrector 212 can be constituted by, for example, coils.

The substrate stage 20 holds the substrate 1, and when drawing is performed on the substrate 1 with a plurality of charged particle beams, moves under the control of a substrate stage control unit 226. The substrate stage 20 includes a measurement unit 21 which measures the position of each charged particle beam emitted from the drawing system 10. The measurement unit 21 includes, for example, knife edges in the X and Y directions, and Faraday cups which detect charged particle beams having passed through the knife edges. While the substrate stage 20 is moved in the X and Y directions, the measurement unit 21 detects a charged particle beam by using the Faraday cups, and can measure the position of each charged particle beam emitted from the drawing system 10.

The control system 30 includes, for example, a lens array control unit 220, a blanking control unit 221, the lens control unit 222, a deflection control unit 223, an alignment control unit 224, a stage control unit 225, and the main control unit 226. The lens array control unit adjusts the position of the intermediate image 209 by giving a potential difference to three electrodes constituting the lens array 205. The blanking control unit 221 controls the blanker array 207 based on control data supplied from the main control unit 226. The lens control unit 222 controls the first projection lens 210 and second projection lens 214 so that a focus position at the rear stage of the first projection lens 210 and a focus position at the front stage of the second projection lens 214 coincide with each other. The deflection control unit 223 controls the main deflector 213 and sub-deflector 215 in each drawing unit 11 to individually deflect a plurality of charged particle beam groups. The deflection control unit 223 also controls the dynamic focus corrector 211 and dynamic astigmatism corrector 212. The alignment control unit 224 controls a detection unit 22 (to be described later). The stage control unit 225 controls movement of the substrate stage 20. The main control unit 226 includes a CPU and memory, and comprehensively controls the respective units in the control system 30 (controls drawing processing).

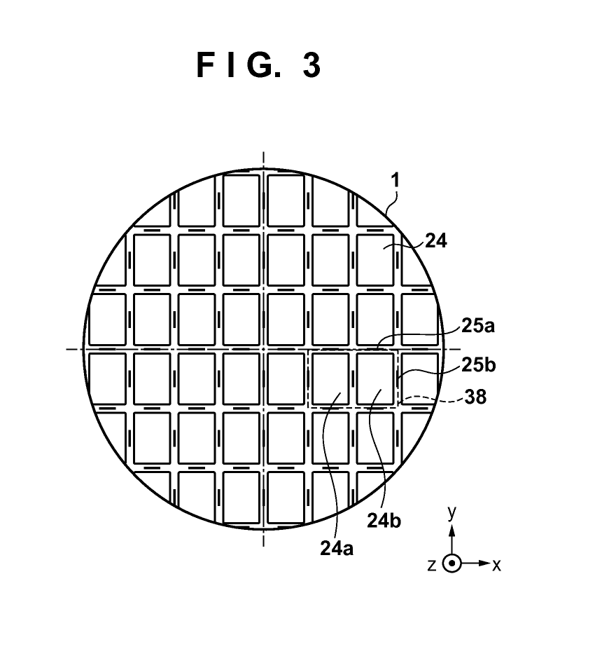

A method of measuring the shape of each of a plurality of shot regions 24 formed on the substrate 1 will be explained. FIG. 3 is a view showing the arrangement of the shot regions 24 and alignment marks 25 (x detection alignment marks 25a and y detection alignment marks 25b) formed on the substrate. In the drawing apparatus 100 according to the first embodiment, as shown in FIG. 1, the detection unit 22 which detects the alignment marks 25 formed on the substrate is arranged near the drawing system 10. The detection unit 22 is controlled by the alignment control unit 224 and detects the plurality of alignment marks 25 arranged around the shot regions 24. The alignment control unit 224 can statistically process signals supplied from the detection unit 22 to calculate the positions of the respective alignment marks 25. Based on the positions of the respective alignment marks 25, the alignment control unit 224 can obtain information of a region on the substrate where the shot region 24 exists, that is, the shapes of the respective shot regions 24 formed on the substrate. The shape obtained by the alignment control unit 224 may contain deformation components such as a shift component, rotation component, and magnification component with respect to a shape to be originally formed. The processing of detecting the plurality of alignment marks 25 formed on the substrate 1 and measuring the shapes of the respective shot regions 24 is called global alignment measurement.

A method of performing drawing on the substrate 1 based on the shape of each shot region 24 obtained by global alignment measurement in the drawing apparatus 100 having the above-described arrangement will be explained. In the first embodiment, drawing is performed in parallel in two shot regions 24a and 24b surrounded by a dotted line in FIG. 3. Regions (regions surrounded by the dotted line in FIG. 3) where drawing is performed in parallel will be called a parallel drawing region 38. When performing drawing in the parallel drawing region 38, the main control unit 226 averages shift components (X and Y directions) and rotation components obtained by global alignment measurement for the shot regions 24a and 24b. For are the respective components of the shot regions 24a and 24b. At this time, the average values of the respective components of the shot regions 24a and 24b can be given by:

xₐᵥₑ=(xₛ₂₄ₐ+x_{s24b})/2

yₐᵥₑ=(yₛ₂₄ₐ+y_{s24b})/2

Rotₐᵥₑ=(Rotₛ₂₄ₐ+Rot_{s24b})/2 (1)

The thus-obtained average values (xₐᵥₑ, yₐᵥₑ, Rotₐᵥₑ) of the respective components are used as the offset amount of the moving amount of the substrate stage 20 when the substrate 1 is arranged at a position at which drawing in the shot regions 24a and 24b starts. That is, when a plurality of deflectors individually control the positions of a plurality of charged particle beam groups, the position of the substrate stage 20 is controlled to decrease the maximum value of a deflection amount by which each charged particle beam group is deflected.

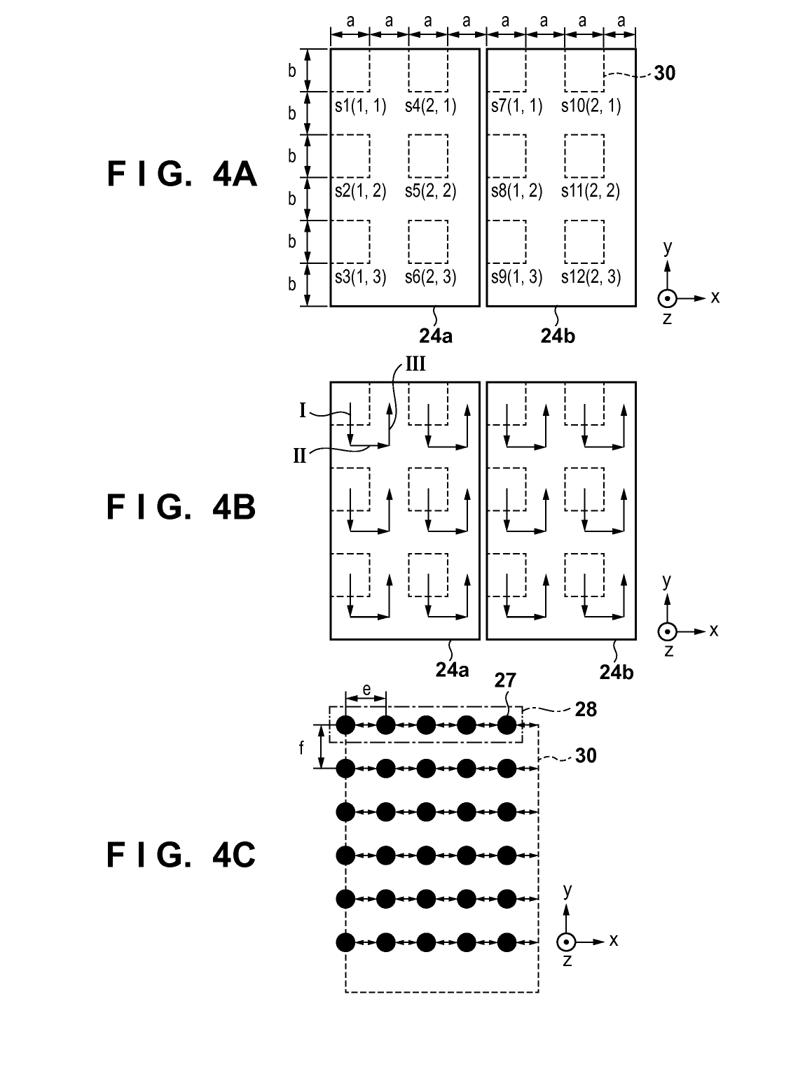

Next, a method of starting drawing on the substrate 1 with a plurality of charged particle beams after moving the substrate stage 20 in the above-described manner will be explained with reference to FIGS. 4A, 4B, and 4C. Assume that, when performing drawing in the parallel drawing region 38, each shot region 24 in the parallel drawing region 38 is irradiated with, for example, six charged particle beam groups. As shown in FIG. 4C, each charged particle beam group includes, for example, 30 charged particle beams (filled circles 27) arrayed in five lines at an interval e in the X direction and six lines at an interval f in the Y direction. Each charged particle beam group is deflected at once in the X direction by the main deflector 213 and sub-deflector 215 while the substrate 1 moves in the Y direction. In FIG. 4A, regions 30 each indicated by a dotted square are regions where drawing is performed with one charged particle beam group when the substrate stage 20 moves in the Y direction by the same distance as the interval f. In the following description, regions s1 to s6 are the regions 30 in the shot region 24a, and regions s7 to s12 are the regions 30 in the shot region 24b. In FIG. 4A, coordinates (m_{g}, m_{y}) are represented for the respective regions 30, that is, s1 to s12. For example, coordinates (1, 2) are represented for the region s2. These coordinates indicate that the region s2 is the region 30 which is the first in the X direction and the second in the Y direction by using the upper left corner of the shot region 24a as the reference, out of the six regions 30 in the shot region 24a. In this step of performing drawing in each region 30, for example, the substrate stage 20 is moved to arrange each region 30 in the order of positions I→II→III shown in FIG. 4B, and drawing with each charged particle beam group is performed at each position. Accordingly, drawing can be performed in the shot regions 24a and 24b in the parallel drawing region 38.

FIGS. 4A to 4C shows a case in which the shapes of the shot regions 24a and 24b formed on the substrate are shapes to be originally formed. However, the shot region 24 formed on the substrate is sometimes formed in a shape different from a shape to be originally formed. When the shot region 24 is formed on the substrate in this manner, it may become difficult to draw a pattern in the shot region 24 at high precision.

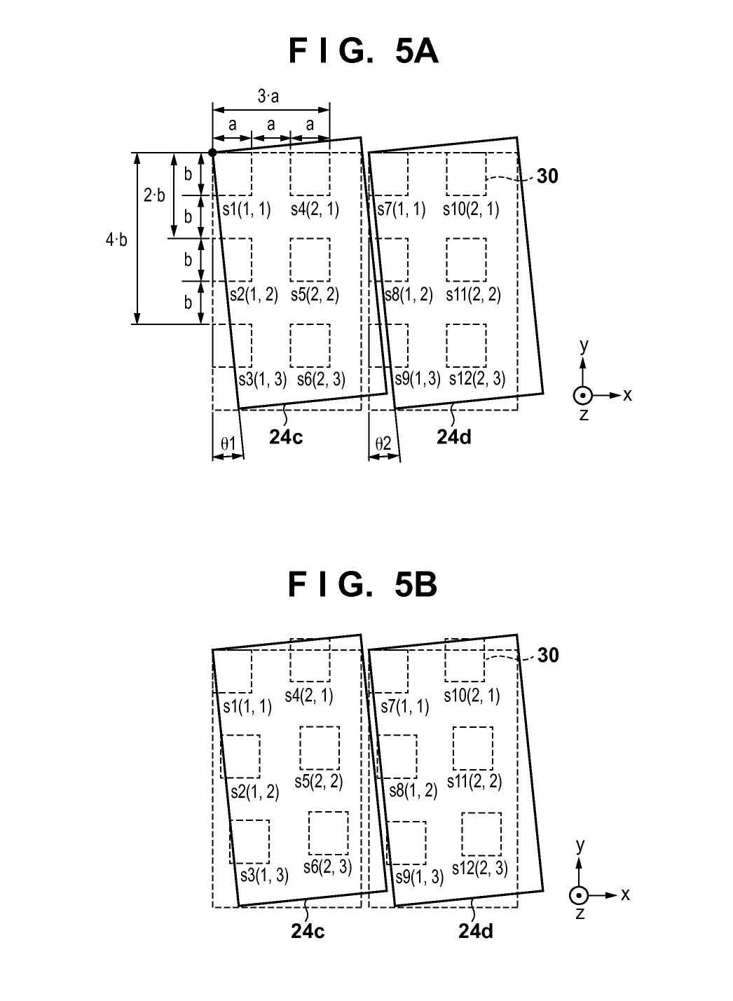

FIGS. 5A and 5B are views showing a case in which the shape of the shot region 24 in the parallel drawing region 38 contains a rotation component, that is, a case in which the shot region 24 exists on the substrate at a rotation angle. In FIG. 5A, shot regions 24c and 24d each indicated by a solid line are the shot regions 24 included in the parallel drawing region 38, and are formed on the substrate in a state in which they are rotated by θ1 and θ2 with respect to the shapes (broken lines) of the shot regions 24 to be originally formed. θ1 and θ2 are obtained by the above-described global alignment measurement. In this case, the positions of the regions 30, that is, s1 to s12 are decided for the shapes of the shot regions 24 to be originally formed. When drawing is performed in this state, drawing may be performed at positions shifted from the shot regions 24c and 24d each containing the rotation component. When θ1=θ2, the rotation components can be corrected by rotating the substrate stage 20 in some cases. However, when θ1≠θ2, it is difficult to individually correct the rotation components in the shot regions 24c and 24d by only rotating the substrate stage 20. As a result, portions not irradiated with charged particle beams are generated in the shot regions 24c and 24d, and the overlay precision may drop. In the drawing apparatus 100 according to the first embodiment, the reference position of each charged particle beam group is adjusted in accordance with the shape of the shot region 24 formed on the substrate 1 for each charged particle beam group by the deflectors (main deflector 213 and sub-deflector 215) in each drawing unit 11. The reference position of each charged particle beam group is a position serving as a reference when each drawing unit 11 scans a charged particle beam group, and is the position of the charged particle beam group at the start of scanning the charged particle beam group. That is, scanning of each charged particle beam group starts from its reference position.

Next, the adjustment amount in each charged particle beam group will be explained. For example, when the shot region 24 rotates at an angle θp, the adjustment amounts ΔSn_x and ΔSn_y of each charged particle beam group in the X and Y directions can be calculated by:

ΔSn_{—}x=Ly×(m_{y}−1)×tan(θp)

ΔSn_{—}y={Lx×(mₓ−1)+Lsx}×tan(θp) (2)

where Lx is the interval of the charged particle beam group in the X direction (interval of the region 30 in the X direction), Ly is the interval of the charged particle beam group in the Y direction (interval of the region 30 in the Y direction), Lsx is the width of the region 30 in the X direction, and mₓ and m_{y} are the coordinates of the region 30 in the X and Y directions, respectively, as described above.

For example, the adjustment amounts ΔS1_{—}x and ΔS1_{—}y of the charged particle beam group for performing drawing in the region s1 shown in FIG. 5A are given based on Lx=2a, Ly=2b, (mx, my)=(1, 1), Lsx=a, and θp=θ1:

ΔS1_{—}x=2b×(1−1)×tan θ1=0

ΔS1_{—}y={2a×(1−1)+a}×tan θ1=a×tan θ1 (3)

Similarly, the adjustment amounts ΔS2_{—}x and ΔS2_{—}y of the charged particle beam group for performing drawing in the region s2 shown in FIG. 5A are given based on Lx=2a, Ly=2b, (mx, my)=(1, 2), Lsx=a, and θp=θ1:

ΔS2_{—}x=2b×(2−1)×tan θ1=2b×tan θ1

ΔS2_{—}y={2a×(1−1)+a}×tan θ1=a×tan θ1 (4)

The adjustment amounts in each charged particle beam group are calculated in this fashion, respectively, and the main control unit 226 controls the deflectors (main deflector 213 and sub-deflector 215) of each drawing unit 11 based on the calculated adjustment amounts. In the drawing apparatus 100 according to the first embodiment, the reference position of each charged particle beam group can be adjusted in accordance with the shape of the shot region 24 formed on the substrate 1, as shown in FIG. 5B. That is, in the drawing apparatus 100 according to the first embodiment, the plurality of regions 30 where drawing is performed with corresponding charged particle beam groups can be arranged in accordance with the shape of the shot region 24 formed on the substrate 1. The first embodiment has described a case in which each shot region 24 formed on the substrate contains only a rotation component. However, each shot region 24 sometimes contains shift components Ex and Ey in the X and Y directions, in addition to the rotation component. In this case, the main control unit 226 may control the deflectors (main deflector 213 and sub-deflector 215) of each drawing unit 11 by moving the substrate stage 20 by only the average values of shift components in the shot region 24 to correct remaining shift components. When the shift components of each shot region 24 can be corrected by only the deflectors of each drawing unit 11, it is unnecessary to move the substrate stage 20. In the first embodiment, the parallel drawing region 38 includes two shot regions 24, and the method of performing drawing in the shot regions 24 in parallel has been explained. However, the present invention is not limited to this. For example, the present invention is also applicable to a case in which the parallel drawing region 38 includes three or more shot regions 24 and drawing is performed in them in parallel, and a case in which the parallel drawing region 38 includes one shot region 24 and drawing is performed in the shot region 24.

As described above, the drawing apparatus 100 according to the first embodiment adjusts the reference position of each charged particle beam group in accordance with the shape of the shot region 24 formed on the substrate 1 for each charged particle beam group by the deflectors of each drawing unit 11. Even when the shot region 24 formed on the substrate 1 contains a rotation component, a pattern can be drawn in the shot region 24 at high precision.

The drawing apparatus 100 according to the first embodiment includes the plurality of drawing units 11 each including the charged particle source 201, and a plurality of charged particle beams emitted from one drawing unit 11 constitute one charged particle beam group. However, the present invention is not limited to this. For example, a plurality of charged particle beam groups may be defined for a plurality of charged particle beams emitted from one drawing unit 11. In this case, the drawing unit 11 can include the deflectors (main deflector 213 and sub-deflector 215) in correspondence with each of the plurality of charged particle beam groups. In this case, the drawing apparatus 100 may be configured to include only one drawing unit 11.

### Second Embodiment

The second embodiment will explain a method of controlling each of a plurality of charged particle beams included in each charged particle beam group when a shot region 24 formed on a substrate 1 contains a rotation component. FIG. 6 is a view showing the arrangement of shot regions 24e and 24f in a parallel drawing region 38, and regions 30 where drawing is performed with a charged particle beam group. In FIG. 6, assume that the shot region 24e is formed on the substrate 1 in a shape to be originally formed, and does not contain deformation components such as a shift component, rotation component, and magnification component. In contrast, assume that the shot region 24f is formed on the substrate in a state in which it is rotated by an angle θ3. The angle θ3 is obtained by global alignment measurement. Assume that adjustment of the reference position described in the first embodiment has already been performed in each charged particle beam group for performing drawing in the shot region 24f, as shown in FIG. 6.

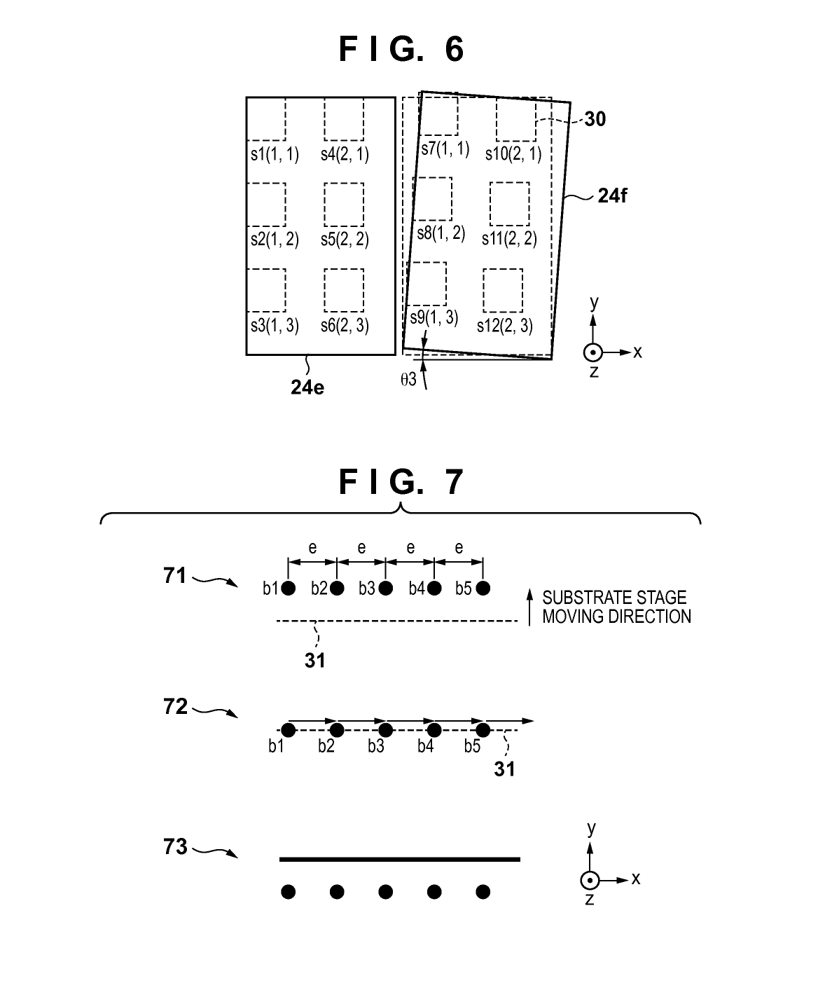

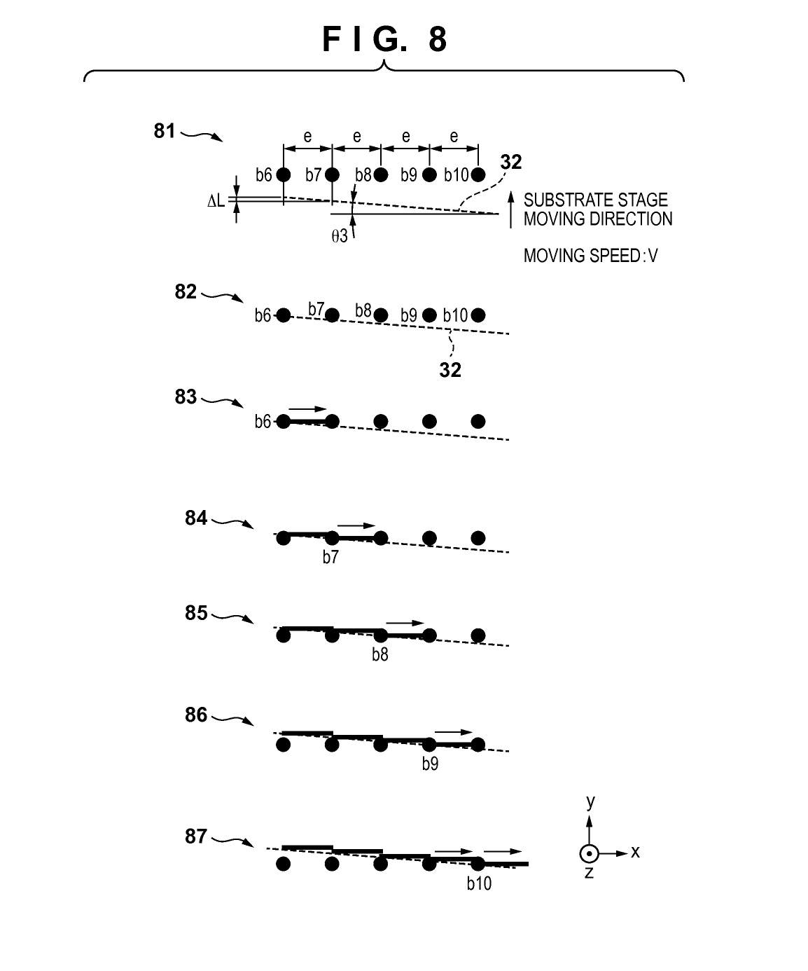

FIGS. 7 and 8 are views showing a step of performing drawing with a plurality of charged particle beams (for example, a subject (or intended) charged particle beam array 28 shown in FIG. 4C) arrayed in the X direction, out of a plurality of charged particle beams included in the charged particle beam group 24e. A line 31 indicated by a dotted line in FIG. 7 represents a pattern to be drawn with the subject charged particle beam array 28 in the shot region 24e shown in FIG. 6. A line 32 indicated by a dotted line in FIG. 8 represents a pattern to be drawn by the subject charged particle beam array 28 in the shot region 24f shown in FIG. 6. Since the shot region 24f is rotated by the angle θ3, the line 32 is inclined by the angle θ3 along with this.

First, a step of performing drawing in the shot region 24e containing no deformation component will be explained with reference to FIG. 7. Charged particle beams b1 to b5 in the subject charged particle beam array 28 are arranged at an interval e, as represented by 71 of FIG. 7. The line 31 indicated by a dotted line represents a line pattern to be drawn with the charged particle beams b1 to b5. When drawing the line 31 with the charged particle beams b1 to b5, a main control unit 226 controls a blanker array 207 and deflectors (main deflector 213 and sub-deflector 215) while moving a substrate stage 20 in the Y direction. For example, when the line 31 is arranged at the irradiation positions of the charged particle beams b1 to b5, as represented by 72 of FIG. 7, the main control unit 226 performs drawing while deflecting the charged particle beams b1 to b5 in the X direction by a distance e. The line 31 can therefore be drawn, as represented by 73 of FIG. 7. To perform this drawing, the main control unit 226 generates control data for controlling drawing with each charged particle beam, and controls the blanker array 207 and deflectors (main deflector 213 and sub-deflector 215) based on the control data. Control data D(bn) for controlling each charged particle beam contains, for example, deflection start time ts_n, a deflection distance Lx, irradiation start time tₛₜₐᵣₜ_{_{—}}n, and irradiation finish time t_{finish}_{₁₃}n, as represented by:

D(bn)=(ts_{—}n, Lx_{—}n, tₛₜₐᵣₜ_{—}n, t_{finish}_{_{—}}n) (5)

The deflection start time ts_n represents the time when deflection by the deflectors starts. The deflection distance Lx represents the distance in the X direction by which a charged particle beam is scanned on the substrate. The irradiation start time tₛₜₐᵣₜ_{_{—}}n represents the time when the blanker array 207 starts irradiation of the substrate with a charged particle beam. The irradiation finish time t_{finish}_{_{—}}n represents the time when the blanker array 207 finishes irradiation of the substrate with a charged particle beam. n represents a number assigned to each charged particle beam.

Since the charged particle beams b1 to b5 are changed at once by the deflectors, the deflection start times ts_n of the charged particle beams b1 to b5 are the same (ts_n=t). Since the length of the line 31 is 5e, the deflection distance Lx_n for each charged particle beam is e. Since the shot region 24e does not contain a rotation component, as described above, the line 31 is not inclined. For this reason, the irradiation start times tₛₜₐᵣₜ_{_{—}}n and irradiation finish times t_{finish}_{_{—}}n of the charged particle beams b1 to b5 are the same (tₛₜₐᵣₜ_{_{—}}n=tₛₜ, t_{finish}_{_{—}}n=t_{fn}). At this time, control data for controlling the charged particle beams b1 to b5 are generated by:

D(b1)=(t, e, tₛₜ, t_{fn})

D(b2)=(t, e, tₛₜ, t_{fn})

D(b3)=(t, e, tₛₜ, t_{fn})

D(b4)=(t, e, tₛₜ, t_{fn})

D(b5)=(t, e, tₛₜ, t_{fn}) (6)

Next, a step of performing drawing in the shot region 24f containing a rotation component will be explained with reference to FIG. 8. Charged particle beams b6 to b10 in the subject charged particle beam array are arranged at the interval e, as represented by 81 of FIG. 8. The line 32 indicated by a dotted line represents a line pattern to be drawn with the charged particle beams b6 to b10. Since the shot region 24f is rotated by the angle θ3, as described above, the line 32 is inclined by the angle θ3 along with this. In drawing the line 32 with the charged particle beams b6 to b10, when the line 32 is arranged at the irradiation position of the charged particle beam b6 (82 in FIG. 8), the main control unit 226 performs drawing while deflecting the charged particle beam b6 by the distance e in the X direction (83 in FIG. 8). When the line 32 is arranged at the irradiation position of the charged particle beam b7, the main control unit 226 performs drawing while deflecting the charged particle beam b7 by e in the X direction (84 in FIG. 8). Similarly, when the line 32 is arranged at the irradiation positions of the charged particle beams b8 to b10, the main control unit 226 performs drawing while deflecting the charged particle beams b8 to b10 by e in the X direction (85 to 87 in FIG. 8). As a result, the line 32 can be drawn, as represented by 87 of FIG. 8. When controlling drawing with the charged particle beams b6 to b10 in this way, control data for controlling the charged particle beams b6 to b10 are generated by:

D(b6)=(t, e, tₛₜ, t_{fn})

D(b7)=(t+ΔT, e, tₛₜ, t_{fn})

D(b8)=(t+2×ΔT, e, tₛₜ, t_{fn})

D(b9)=(t+3×ΔT, e, tₛₜ, t_{fn})

D(b10)=(t+4×ΔT, e, tₛₜ, t_{fn}) (7)

Since the line 32 is inclined by the angle θ3, the deflection start times ts_n of the charged particle beams b6 to b10 are different, and a delay time ΔT is generated between two adjacent charged particle beams. Letting V be the moving speed of the substrate stage 20, ΔL in 81 of FIG. 8 is represented by (e×tan θ3), and the delay time ΔT is given by:

$$\begin{matrix}Δ T = Δ L / V \\ = ( e \times tan θ 3 ) / V\end{matrix} \qquad ( 8 )$$

As described above, when the line 32 to be drawn is inclined, control data for controlling the charged particle beams b6 to b10 are generated so that the deflection start time shifts between two adjacent charged particle beams in accordance with the inclination of the line 32. By controlling the blanker array 207 and deflectors based on the control data, the main control unit 226 can perform drawing at high precision in a shot region containing a rotation component.

In the second embodiment, the charged particle beams b6 to b10 have the same irradiation start time and the same irradiation finish time with respect to the deflection start time on the assumption that a pattern is drawn on the entire line 32. However, the present invention is not limited to this. For example, a pattern to be drawn may be scattered on the line 32. In this case, the irradiation start time and irradiation finish time with respect to the deflection start time may be different between the charged particle beams b6 to b10. In the second embodiment, control data is generated to contain the deflection start time, deflection distance, irradiation start time, and irradiation finish time. However, the present invention is not limited to this. For example, when all charged particle beams are deflected at once, control data may be generated to contain the coordinates (gₓ, g_{y}) of a pattern to be drawn on a substrate, and the ON/OFF control timings tₒₙ and t_{off} of the blanker array 207:

D(bn)=(gₓn, g_{y}n, tₒₙn, t_{off} n) (9)

### Third Embodiment

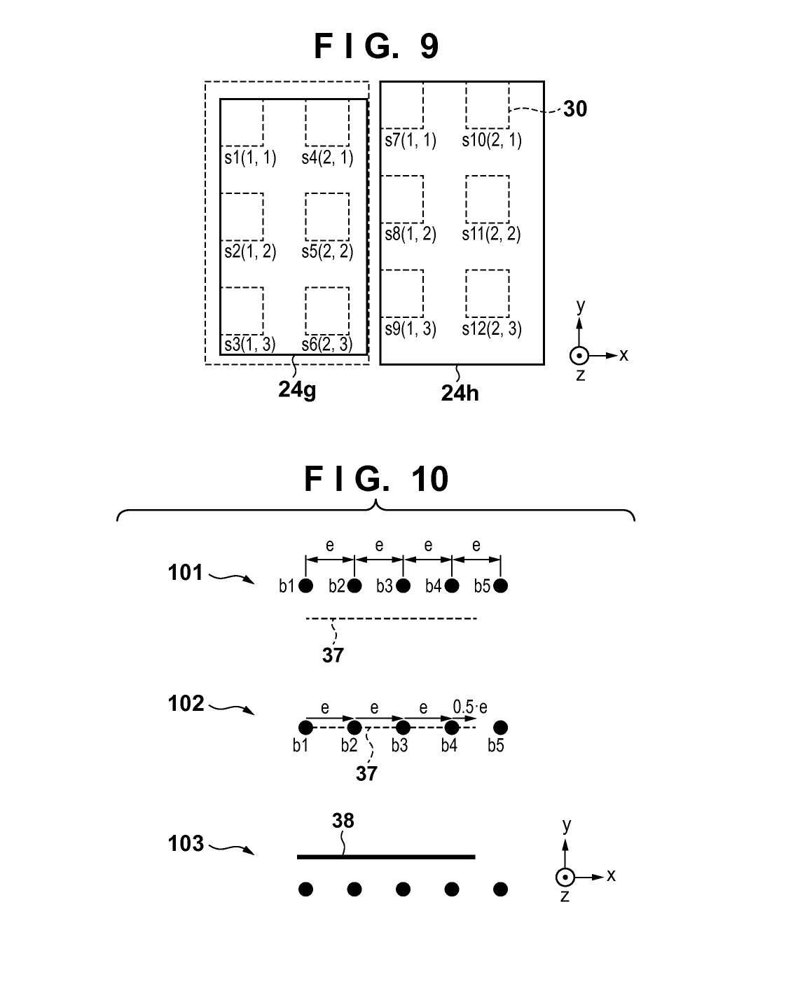

The third embodiment will explain a method of controlling each of a plurality of charged particle beams included in each charged particle beam group when a shot region 24 formed on a substrate 1 contains a magnification component, that is, when the shot region 24 exists on the substrate at a magnification. FIG. 9 is a view showing the arrangement of shot regions 24g and 24h where drawing is performed in parallel, and regions 30 where drawing is performed with a charged particle beam group. In FIG. 9, assume that the shot region 24h is formed on the substrate 1 in a shape to be originally formed, and does not contain deformation components such as a shift component, rotation component, and magnification component. In contrast, assume that the shot region 24g is formed on the substrate in a state in which it is contracted from a shape to be originally formed. Assume that adjustment of the reference position described in the first embodiment has already been performed in each charged particle beam group for performing drawing in the shot region 24g, as shown in FIG. 9.

FIG. 10 is a view showing a step of performing drawing in the shot region 24 with a plurality of charged particle beams (for example, a subject charged particle beam array 28 shown in FIG. 5C) arrayed in the X direction, out of a plurality of charged particle beams included in one charged particle beam group. A line 37 indicated by a dotted line in 101 of FIG. 10 represents a pattern (length of 3.5×e) to be drawn with a plurality of charged particle beams b1 to b5 in the subject charged particle beam array 28 in the shot region 24g shown in FIG. 9. The line 37 should have a length of 5×e in a state in which the shot region 24 is not contracted. However, the line 37 has the length of 3.5×e owing to the contraction of the shot region 24, as represented by 101 of FIG. 10. In this case, when the line 37 is arranged at the irradiation positions of the charged particle beams b1 to b5, as represented by 102 of FIG. 10, a main control unit 226 performs drawing by the distance e in the X direction with the charged particle beams b1 to b3. To the contrary, the main control unit 226 performs drawing by a distance of 0.5×e in the X direction with the charged particle beam b4, and does not perform drawing with the charged particle beam b5. As a result, the line 37 can be drawn, as represented by 103 of FIG. 10. To achieve this, the main control unit 226 sets the irradiation finish time in control data for controlling the charged particle beam b4, so as to perform drawing by only the distance of 0.5×e. Also, the main control unit 226 sets the irradiation start time in control data for controlling the charged particle beam b5, so as not to perform drawing, that is, not to start irradiation of the substrate 1 with the charged particle beam b5.

In this manner, when the shot region 24 contains a magnification component, and the line 37 to be drawn is expanded or contracted, the range where drawing is performed with each charged particle beam is changed in accordance with the shape of the shot region 24, and control data for controlling each charged particle beam is generated based on the changed range. By controlling a blanker array 207 and deflectors (main deflector 213 and sub-deflector 215) based on the control data, the main control unit 226 can perform drawing at high precision in the shot region 24 containing a magnification component.

### Fourth Embodiment

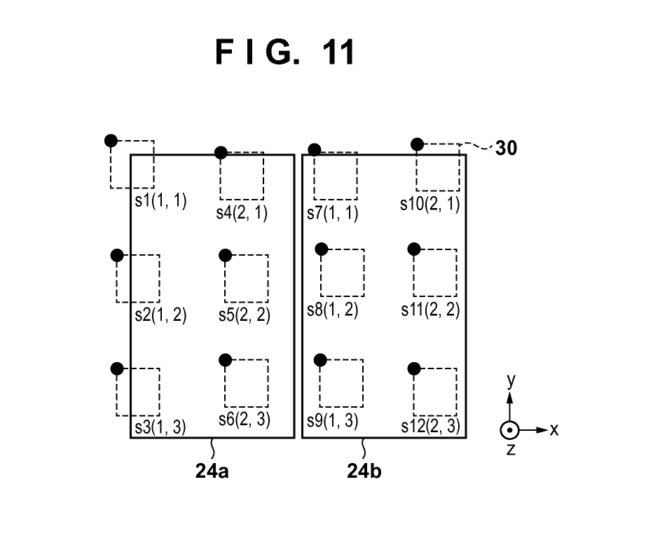

The fourth embodiment will explain a case in which the reference position of each charged particle beam group shifts from a target position owing to, for example, a temporal change of a member used in a drawing unit 11. FIG. 11 is a view showing the arrangement of shot regions 24a and 24b where drawing is performed in parallel, and regions 30 where drawing is performed with a charged particle beam group. In FIG. 11, a filled circle in each region 30 is a position of a substrate 1 that is irradiated with a charged particle beam (to be referred to as a reference line hereinafter) serving as a reference in each charged particle beam group. In FIG. 11, the shot regions 24a and 24b are formed on the substrate 1 in a shape to be originally formed, and do not contain deformation components such as a shift component, rotation component, and magnification component. However, a position shift is generated in each region 30 to be drawn with each charged particle beam group, as shown in FIG. 11. This position shift may be generated by an error when a plurality of drawing units 11 are installed, a temporal change of a member used in each drawing unit 11, and the like. When the position shift of each charged particle beam group is generated, a main control unit 226 measures the position of the reference line of each charged particle beam group by using a measurement unit 21. The main control unit 226 can obtain the position shift of each charged particle beam group in accordance with the measurement result of the position of the reference line. The main control unit 226 decides, for each charged particle beam group, a deflection amount for deflecting a charged particle beam group to correct the obtained position shift of the charged particle beam group. The decided deflection amount is added to an adjustment amount for adjusting the reference position of each charged particle beam group in accordance with the shape of a shot region 24. That is, when a position shift is generated in each charged particle beam group, deflectors (main deflector 213 and sub-deflector 215) are controlled to perform even correction of the position shift, in addition to adjustment complying with the shape of the shot region 24 in each charged particle beam group.

In this way, when a position shift is generated in each charged particle beam group, the deflectors are controlled to correct the position shift, in addition to adjustment complying with the shape of the shot region 24 in each charged particle beam group. Even when the irradiation position of the charged particle beam group on the substrate 1 shifts, a pattern can be drawn at high precision in the shot region 24 formed on the substrate 1.

### Embodiment of Method of Manufacturing Article

A method of manufacturing an article according to the embodiment of the present invention is suitable for manufacturing an article such as a microdevice (for example, a semiconductor device) or an element having a microstructure. The method of manufacturing an article according to the embodiment includes a step of forming, by using the above-described drawing apparatus, a latent image pattern on a photosensitive agent applied to a substrate (a step of performing drawing on a substrate), and a step of developing the substrate on which the latent image pattern has been formed in the preceding step. Further, this manufacturing method includes other well-known steps (for example, oxidization, deposition, vapor deposition, doping, planarization, etching, resist removal, dicing, bonding, and packaging). The method of manufacturing an article according to the embodiment is superior to a conventional method in at least one of the performance, quality, productivity, and production cost of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-167842 filed on Aug. 12, 2013, which is hereby incorporated by reference herein in its entirety.

What is claimed is:

1. A drawing apparatus which performs drawing on a substrate with a plurality of charged particle beams, the apparatus comprising:
a blanker array including a plurality of blankers and configured to individually blank the plurality of charged particle beams;
a plurality of deflectors configured to individually deflect a plurality of charged particle beam groups constituting the plurality of charged particle beams; and
a controller configured to individually control positions of the plurality of charged particle beam groups by the plurality of deflectors, and individually control blanking of the plurality of charged particle beams by the blanker array, based on information of a region on the substrate where a shot region exists.

2. The apparatus according to claim 1, wherein if the shot region exists on the substrate with a rotation angle, the controller is configured to control the blanker array based on the rotation angle.

3. The apparatus according to claim 1, wherein if the shot region exists on the substrate with a magnification, the controller is configured to control the blanker array based on the magnification.

4. The apparatus according to claim 1, wherein
the apparatus is configured to perform drawing in parallel with respect to at least two shot regions on the substrate, and
the plurality of charged particle beam groups are arranged to perform drawing with respect to each of the at least two shot regions with at least one charged particle beam group of the plurality of charged particle beam groups.

5. The apparatus according to claim 4, further comprising a substrate stage configured to hold the substrate and to be movable,
wherein the controller is configured to control a position of the substrate stage so as to decrease a maximum value of deflection amounts of the plurality of charged particle beam groups by the plurality of deflectors in a case where positions of the plurality of charged particle beam groups are individually controlled.

6. The apparatus according to claim 1, further comprising a measurement device configured to measure a position of each charged particle beam included in each of the plurality of charged particle beam groups,
wherein the controller is configured to individually control the positions of the plurality of charged particle beam groups by the plurality of deflectors based on measurement by the measurement device.

7. A method of manufacturing an article, the method comprising:
performing drawing on a substrate using a drawing apparatus;
developing the substrate on which the drawing has been performed; and
processing the developed substrate to manufacture the article,
wherein the drawing apparatus performs drawing on the substrate with a plurality of charged particle beams, and includes:
a blanker array including a plurality of blankers and configured to individually blank the plurality of charged particle beams;
a plurality of deflectors configured to individually deflect a plurality of charged particle beam groups constituting the plurality of charged particle beams; and
a controller configured to individually control positions of the plurality of charged particle beam groups by the plurality of deflectors, and individually control blanking of the plurality of charged particle beams by the blanker array, based on information of a region on the substrate where a shot region exists.
